(19) United States
(12) Patent Application Publication
(10) Pub. No.: US 2004/0095714 A1
(43) Pub. Date: May 20, 2004

(54) Snapping mechanism for CPU cooler

(75) Inventor: Jung Tsan Chen, Sanchung City (TW)

Correspondence Address: BACON & THOMAS, PLLC, 625 SLATERS LANE, FOURTH FLOOR, ALEXANDRIA, VA, 22314

(73) Assignee: KOCAM INTERNATIONAL CO., LTD., Sanchung City (TW)

(21) Appl. No.: 10/298,592

(22) Filed: Nov. 19, 2002

(51) Int. Cl. H05K 5/00

(52) U.S. Cl. 361/683

(57) ABSTRACT

The invention is to provide a snapping device comprising an elongated clinging mechanism including a pivotal lever at either end wherein centers of rotation of the pivotal levers and the clinging mechanism are at different horizontal levels; and two post-shaped resilient elements disposed adjacent ends of the clinging mechanism wherein each resilient element passes through a support of a cooler and a circuit board to secure to an abutment plate at the other opposite side of the circuit board, the resilient elements will be expanded if the pivotal levers are rotated, and the clinging mechanism is mounted on the cooler by a stored returning force of the expanded resilient elements, thereby stably resting the cooler one a chip member on the circuit board.

### FIELD OF THE INVENTION

The present invention relates to fastening of a cooler on CPU (central processing unit) and more particularly to an improved snapping mechanism for reliably fastening the CPU cooler and increasing a heat dissipation capability of the CPU cooler.

### BACKGROUND OF THE INVENTION

Electronics technology has known a rapid, spectacular development leading to an increasing use of electronic and telecommunication products. One of the products is computer in which CPU, being compact, multifunctional, and easy to use, is the most important element of the computer. Moreover, CPU is lightweight, slim, and dense, thus enabling it to become a leading component in the development of many electronic products. It is known that CPU is the operational center of computer or so-called brain of the computer. It is also known a running speed (i.e., operating speed) of CPU has been increased significantly due to the improvement of computer technology and IC (integrated circuit) manufacturing process. This also means that more heat is generated by CPU as the running speed thereof increases. As such, it is understood that performance of CPU and thus the associated computer will be adversely affected if heat is not sufficiently driven away from the CPU. A most simple technique for dissipating heat of CPU is to mount a cooler on CPU. It is designed that heat generated by CPU will be dissipated by the cooler so as to maintain a normal operation of CPU.

A conventional cooling assembly for CPU comprises a fan, a cooler, and a snapping member. The fan is secured to a seat above the cooler by means of a plurality of screws. The cooler is clamped to a projected member on a base of motherboard by means of the snapping member. As such, the bottom of the cooler is urged against the top of CPU. As such, heat generated by the CPU will be drawn to the cooler during the running of computer. Heat is then sucked to a heat dissipation region of the cooler by the running fan. As an end, the purpose of driving away heat from CPU is achieved.

However, many CPU cooler manufacturers do not satisfy with such technique of clamping the snapping member to the projected member because they, for ensuring a tight engagement of the cooler and the CPU, may apply a predetermined pressure on the cooler and the pressure is in turn applied on the CPU. As a solution to the above requirement, another prior art CPU cooling assembly is disclosed as shown in FIG. 1. As shown, it comprises a cooler 10, a support 12, a snapping member 14, and an abutment plate 16. The support 12 and the abutment plate 16 are provided on opposite sides of a base 20 of motherboard 2, i.e., the motherboard 2 is sandwiched between the support 12 and the abutment plate 16. The cooler 10 is installed (i.e., secured) on the support 12 by means of the snapping member 14. The snapping member 14 is an elongated member and has two end openings 142. Also, the support 12 has two opposite threaded holes 122 disposed corresponding to the openings 142. Hence, two screws 3 may be driven through the openings 142, the threaded holes 122, and the motherboard 2 to secure to the abutment plate 16. With the fastening of the snapping member 14, the support 12, and the abutment plate 16 by means of the screws 3, a predetermined pressure can be applied on a CPU 22 by the cooler 10.

However, for the purpose of applying a uniform pressure on the CPU 22 a simple single driving of either screw 3 is not adopted. Instead, a stepwise technique of advancing one screw 3 a predetermined distance and then advancing the other screw 3 the same predetermined distance in alternate is implemented until the cooler 10 is fastened. Inevitably, it is a time-consuming process, resulting in an increase of manufacturing cost. Moreover, such stepwise technique is difficult for a novice to perform. Instead, a master technician is preferred. As such, the manufacturing cost is further increased. Furthermore, a mass production is inhibited. Thus improvement exists.

### SUMMARY OF THE INVENTION

A primary object of the present invention is to provide a snapping device comprising an elongated clinging mechanism including a pivotal lever at either end wherein centers of rotation of the pivotal levers and the clinging mechanism are at different horizontal levels; and two post-shaped resilient elements disposed adjacent ends of the clinging mechanism wherein each of the resilient elements passes through a support of a cooler and a circuit board to secure to an abutment plate at the other opposite side of the circuit board, the resilient elements will be expanded if the pivotal levers are rotated, and the clinging mechanism is mounted on the cooler by a stored returning force of the expanded resilient elements, thereby stably resting the cooler one a chip member on the circuit board. By utilizing this snapping device, it is possible of overcoming the above drawbacks of the prior art such as time-consuming screw fastening process and necessary master technicians.

The above and other objects, features and advantages of the present invention will become apparent from the following detailed description taken with the accompanying drawings.

### BRIEF DESCRIPTION OF THE DRAWINGS

FIG. 1 is an exploded view of a conventional CPU cooling assembly;

FIG. 2 is an exploded view of a snapping mechanism for cooler to be mounted on a CPU according to the invention;

FIG. 3 is a perspective view of the FIG. 2;

FIG. 4 is a side view of the FIG. 3 where pivotal lever has not been rotated;

FIG. 5 is a view similar to FIG. 4 where the pivotal lever has been rotated;

FIG. 6 is a side view of a first preferred embodiment of resilient element according to the invention,

FIG. 7 is a side view of a second preferred embodiment of resilient element according to the invention;

FIG. 8 is a side view of a third preferred embodiment of resilient element according to the invention;

FIG. 9 is a side view showing an additional flexible member in a state of not being rotated by the pivotal lever according to the invention; and

FIG. 10 is a view similar to FIG. 9 showing the flexible member in a state of being rotated by the pivotal lever.

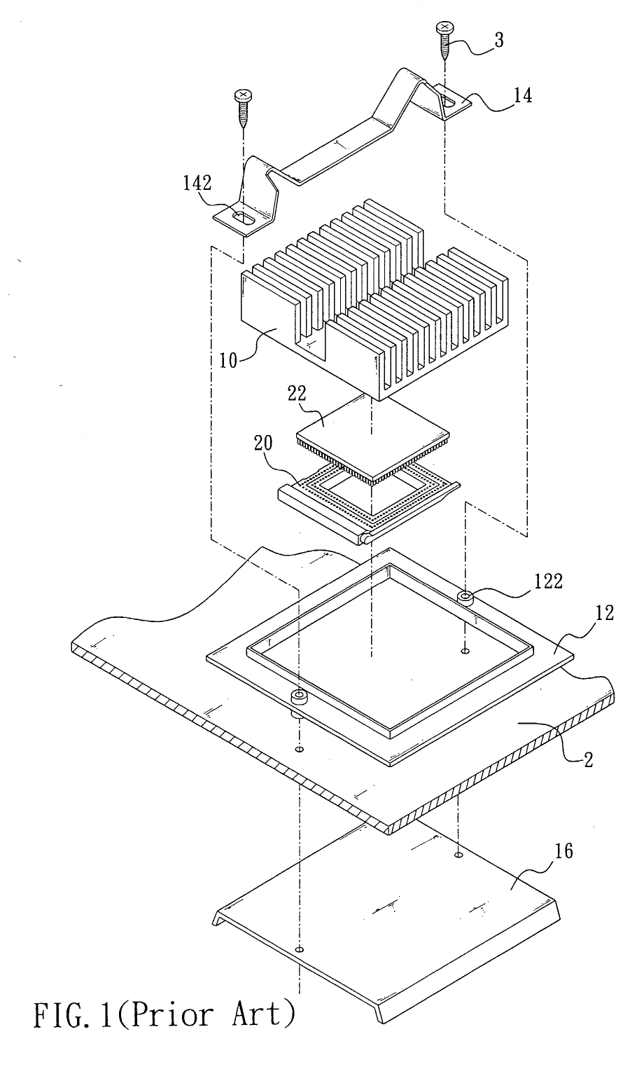

### DETAILED DESCRIPTION OF THE PREFERRED EMBODIMENTS

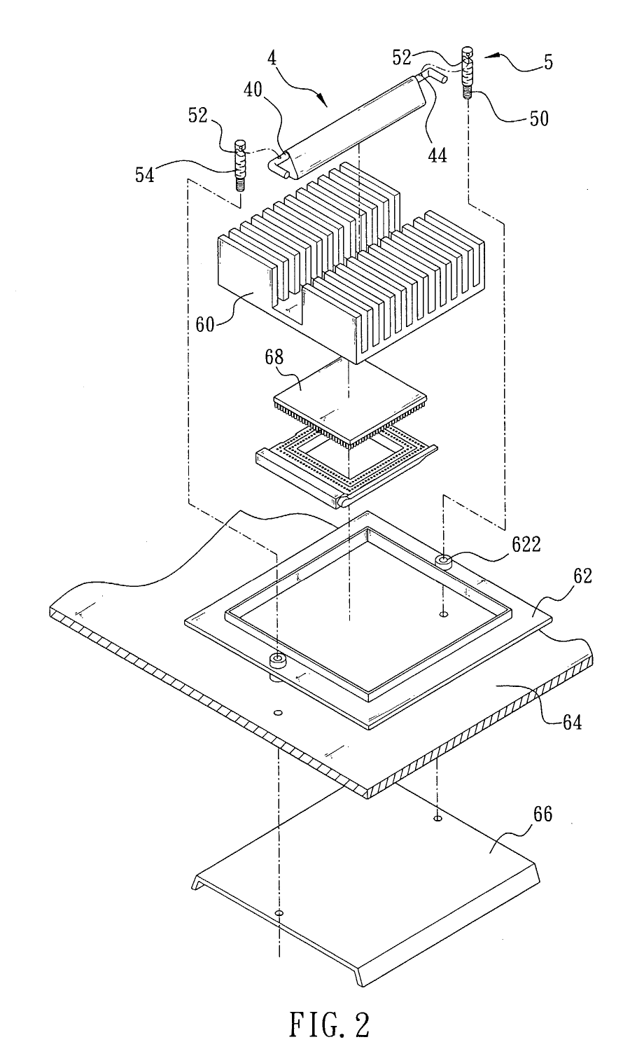

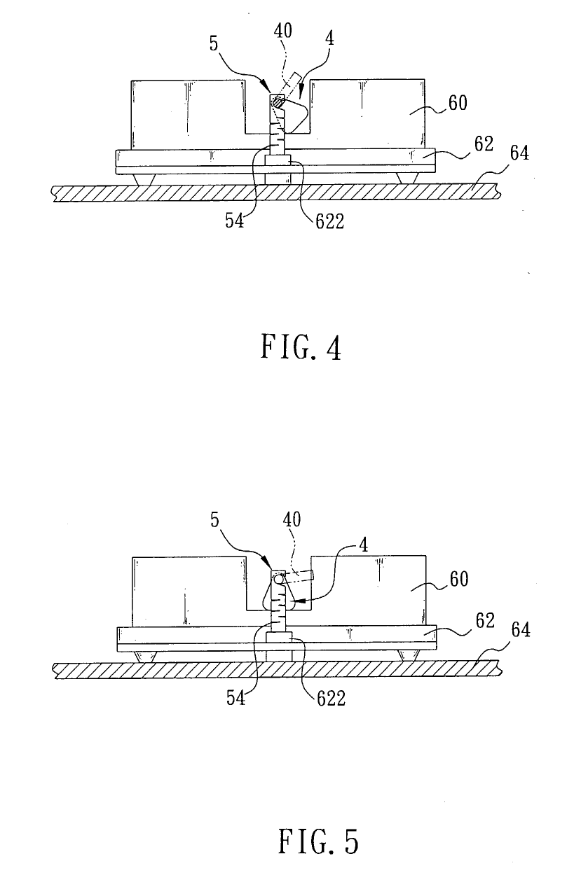

The invention is directed to a snapping mechanism as shown in FIGS. 2 to 10. The snapping mechanism comprises an elongated clinging mechanism 4, and two post-shaped resilient elements 5. An L-shaped pivotal lever 40 is formed at either end of the clinging mechanism 4. Centers of rotation of the pivotal lever 40 and the clinging mechanism 4 are at different horizontal levels. Either resilient element 5 is disposed adjacent one end of the clinging mechanism 4. The resilient element 5 may pass through a rectangular or square, hollow support 62 of a cooler 60 and a circuit board (e.g., motherboard) 64 to secure to an abutment plate 66 at the other opposite side of the circuit board 64. As an end, the clinging mechanism 4 is mounted on the cooler 60 which is in turn in contact with a chip member (e.g., CPU) 68. The resilient elements 5 will be expanded if the pivotal levers 40 are rotated. As a result, the clinging mechanism 4 is urged against the cooler 60 by the expanded resilient elements 5. And in turn, the cooler 60 is stably rested on the CPU 68 for absorbing heat generated while the CPU 68 is running.

In a preferred embodiment of the invention (see FIG. 2), the resilient element 5 comprises a thread member 50 at a lower end. The thread member 50 can be driven through the threaded hole 622 of the support 62 and the circuit board 64 to secure to the abutment plate 66. The resilient element 5 further comprises a recess 52 at one side adjacent an upper end. Two sides of the recess 52 adjacent the resilient element 5 extend toward the other side and the upper end of the resilient element 5. As such, the clinging mechanism 4 can be secured by the recess 52, i.e., the clinging mechanism 4 and the resilient element 5 are fastened together. Further, the center of rotation of the pivotal lever 40 is defined to move and rotate in the recess 52. The resilient element 5 further comprises an elastic section 54 about in the center. The elastic section 54 can be compressed by its elastic nature so as to store energized force in the resilient element 5 for permitting a later expansion of the resilient element 5.

As stated above, the centers of rotation of the pivotal lever 40 and the clinging mechanism 4 are at different horizontal levels. Hence, a maximum distance between the centers of rotation of the pivotal lever 40 and the clinging mechanism 4 is also a maximum expansion distance of the resilient element 5. For the purpose of applying a predetermined pressure on the cooler 60 by means of the clinging mechanism 4, according to engineering mechanics it is designed that the resilient element 5 can be expanded to a predetermined length as long as there is sufficient force stored therein for permitting a later compression under the predetermined pressure. Also, the predetermined length must be less than or equal to the maximum expansion distance.

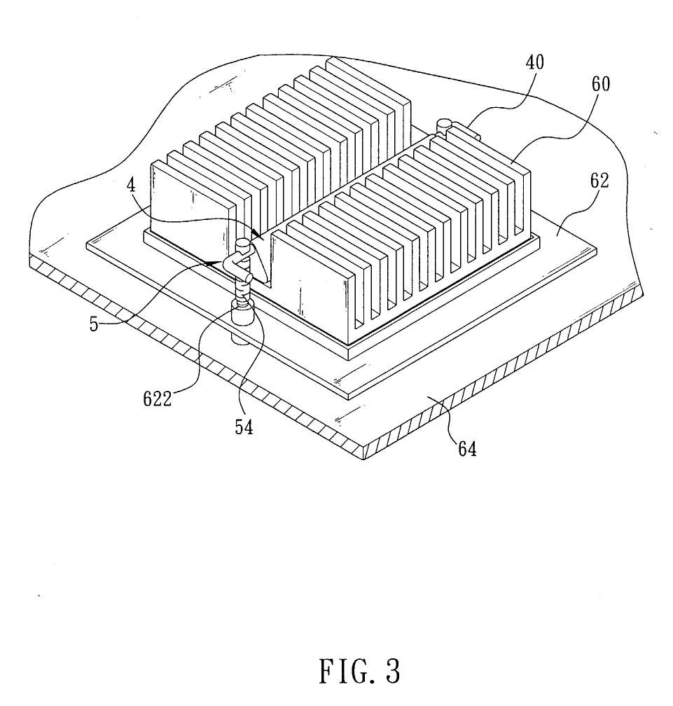

For preventing the secured clinging mechanism 4 from undesirably rotating about the cooler 60 when the clinging mechanism 4 has applied the predetermined pressure on the cooler 60, in another preferred embodiment of the invention as shown in FIGS. 2 and 3, the clinging mechanism 4 further comprises a fastening member 44 on its surface. Correspondingly, the resilient element 5 further comprises a mating fastening member (not shown) in the recess 52. Hence, it is possible of rotating the clinging mechanism 4 to cause the fastening member 44 to snap into the mating fastening member so as to secure the clinging mechanism 4 and the resilient element 5 together in which the resilient element 5 has been expanded to the predetermined length. Also, the clinging mechanism 4 is secured to the cooler 60 without worrying about being undesirably rotated.

In a preferred embodiment of the invention (see FIGS. 2, 4, and 5), the clinging mechanism 4 has a triangular section. The pivotal lever 40 is rotatably secured in the recess 52. Hence, one side of the clinging mechanism 4 is engaged with the cooler 60 when the pivotal lever 40 has been rotated clockwise (see FIG. 5 specifically). At this position, the resilient element 5 is expanded to the predetermined length. As such, the predetermined pressure is applied on the cooler 60 by the clinging mechanism 4. As an end, the clinging mechanism 4 is secured.

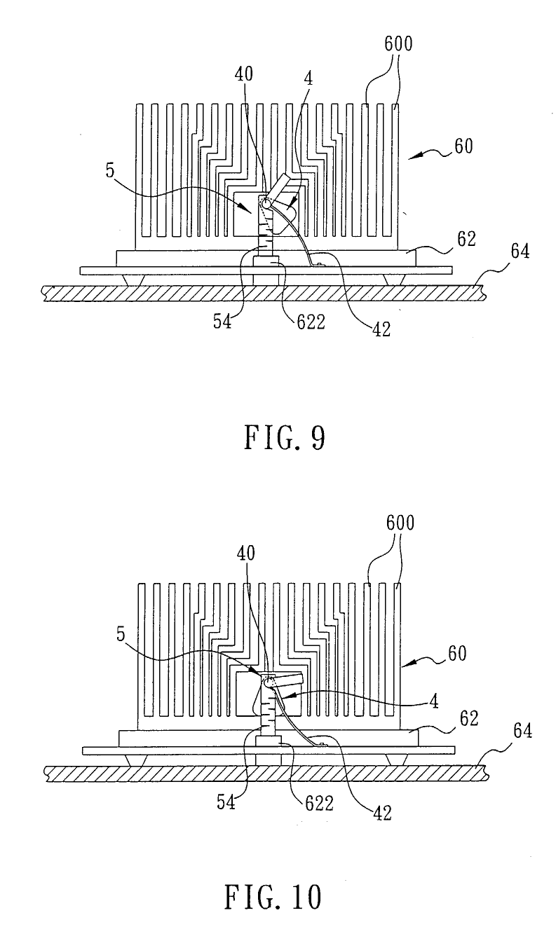

In another preferred embodiment of the invention (see FIGS. 9 and 10), the clinging mechanism 4 further comprises two flexible members 42 each of which is extended from one end thereof to the support 62. The flexible members 42 are deformed when the pivotal levers 40 have been rotated to their maximum. At this position, the resilient element 5 is expanded to the predetermined length. Also, the clinging mechanism 4 is prevented from rotating by the deformed flexible members 42. As such, the predetermined pressure is applied on the cooler 60 by the clinging mechanism 4. As an end, the clinging mechanism 4 is secured. In the embodiment, the flexible member 42 is arcuate and is formed of a resilient metal piece. The flexible member 42 is deformed to another arcuate shape opposite to the original one when the pivotal lever 40 has been rotated to its maximum. As a result, the clinging mechanism 4 is quickly rotated to urge against the cooler 60 by the flexible members 42.

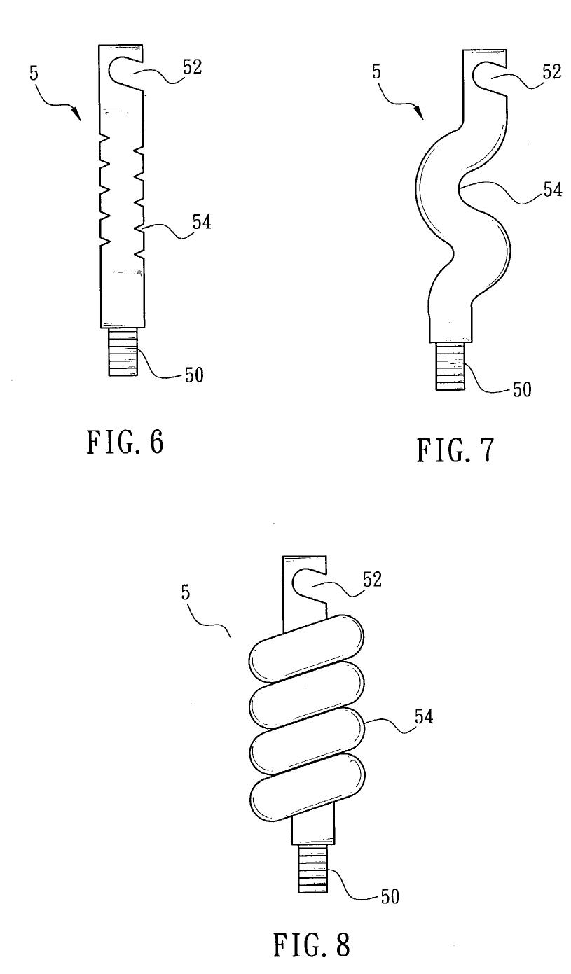

Referring to FIGS. 6, 7, and 8, there are shown three preferred embodiments of the elastic section 54. As shown, the elastic section 54 can be zigzag, continuously curved and winding, or helical shape. Thus, the elastic section 54 can be deformed by compression. Next, the elastic section 54 can return to its original shape as the compression force is removed. Referring to FIGS. 9 and 10, fins 600 of the cooler 60 at one side distal from the support 62 are equally spaced apart. Such design aims to provide a minimum space for installing the clinging mechanism 4 so as to preserve a maximum space for the provision of the fins 600.

While the invention has been described by means of specific embodiments, numerous modifications and variations could be made thereto by those skilled in the art without departing from the scope and spirit of the invention set forth in the claims.

What is claimed is:

1. A snapping device comprising:
an elongated clinging mechanism including a pivotal lever at either end wherein centers of rotation of the pivotal levers and the clinging mechanism are at different horizontal levels; and
two post-shaped resilient elements disposed adjacent ends of the clinging mechanism wherein each of the resilient elements passes through a support of a cooler and a circuit board to secure to an abutment plate at the other opposite side of the circuit board for urging the clinging mechanism against the cooler to cause the cooler to be in contact with a chip member on the circuit board, the resilient elements will be expanded if the pivotal levers are rotated, and the clinging mechanism is mounted on the cooler by a stored returning force of the expanded resilient elements.

2. The snapping device of claim 1, wherein each of the resilient elements comprises:
a thread member at a lower end, the thread member being driven through one of threaded holes of the support and the circuit board to secure to the abutment plate;
a recess at one side of each of the resilient elements adjacent an upper end wherein two sides of the recess adjacent one of the resilient elements extend toward the other side and the upper end of one of the resilient elements so that the clinging mechanism is capable of being secured by the recess for fastening the clinging mechanism and one of the resilient elements together; and
an elastic section about in a center of each of the resilient elements.

3. The snapping device of claim 1, wherein a maximum distance between the centers of rotation of the pivotal levers and the clinging mechanism is a maximum expansion distance of each of the resilient elements so that each of the resilient elements is capable of expanding to a predetermined length less than or equal to the maximum expansion distance as long as there is sufficient force stored therein for permitting a later compression under a predetermined pressure.

4. The snapping device of claim 1, wherein the clinging mechanism further comprises a fastening member on its surface and each of the resilient elements further comprises a mating fastening member in the recess so that it is possible of rotating the clinging mechanism to cause the fastening member to snap into the mating fastening member for securing the clinging mechanism and one of the resilient elements together with the resilient elements been expanded to the predetermined length.

5. The snapping device of claim 1, wherein the clinging mechanism has a triangular section and each of the pivotal levers is rotatably secured in the recess so that one side of the clinging mechanism is engaged with the cooler when the pivotal levers have been rotated to their maximum with the resilient elements expanded to the predetermined length.

6. The snapping device of claim 1, wherein the clinging mechanism further comprises two flexible members each extended from one end thereof to the support, the flexible member being deformed when the pivotal levers have been rotated to their maximum with the resilient elements expanded to the predetermined length.

7. The snapping device of claim 6, wherein each of the flexible members is arcuate and is formed of a resilient metal piece so that each of the flexible members is capable of being deformed to an opposite arcuate shape when the pivotal levers have been rotated to their maximum, thereby quickly rotating the clinging mechanism to urge against the cooler by the flexible members.

8. The snapping device of claim 2, wherein the elastic section has a helical shape.

9. The snapping device of claim 2, wherein the elastic section has a continuously curved and winding shape.

10. The snapping device of claim 2, wherein the elastic section has a zigzag shape.
